(19) United States
(12) Patent Application Publication
(10) Pub. No.: US 2011/0221777 A1
(43) Pub. Date: Sep. 15, 2011

(54) ELECTRONIC DEVICE WITH MOTION SENSING FUNCTION AND METHOD FOR EXECUTING FUNCTIONS BASED ON MOVEMENT OF ELECTRONIC DEVICE

(75) Inventor: JUI-LIN KE, Tu-Cheng (TW)

(73) Assignee: HON HAI PRECISION INDUSTRY CO., LTD., Tu-Cheng (TW)

(21) Appl. No.: 12/845,703

(22) Filed: Jul. 28, 2010

(30) Foreign Application Priority Data
Mar. 10, 2010 (CN) 201010121366.6

(51) Int. Cl. G06F 3/01; G09G 5/00; H03G 3/02; G05B 11/01

(52) U.S. Cl. 345/649; 345/156; 381/109; 700/13

(57) ABSTRACT

An electronic device includes a display unit, a volume control unit, a motion sensor, and a processing unit. The motion sensor is configured to sense the movements of the electronic device rotated around predetermined axes. The processing unit is configured to rotate a currently displayed image a predetermined degree toward a predetermined direction, control the display unit to flip pages, and control the volume adjusting unit to adjust the volume of an opened audio file if the rotation angle of the electronic device rotated around the predetermined axes reaches predetermined angles correspondingly. A related method is also provided.

### BACKGROUND

1. Technical Field

The present disclosure relates to electronic devices and methods and, particularly, to an electronic device with motion sensor function and a method for executing predetermined functions based on the movement of the electronic device.

2. Description of the Related Art

For small-sized electronic devices, it is difficult for users to press keys and/or touch a touch screen to input information correctly to execute functions by the devices.

### BRIEF DESCRIPTION OF THE DRAWINGS

The components of the drawings are not necessarily drawn to scale, the emphasis instead being placed upon clearly illustrating the principles of an electronic device with motion sensor functions and a method for executing predetermined functions based on the movement of the electronic device. Moreover, in the drawings, like reference numerals designate corresponding parts throughout multiple views.

FIG. 1 is a block diagram of an electronic device in accordance with an exemplary embodiment.

FIG. 2 is a schematic view showing that the electronic device is rotated around a first axis.

FIG. 3 is a schematic view showing that the electronic device is rotated around a second axis and a third axis.

FIG. 4 is a flowchart of a method for executing predetermined functions based on movement of the electronic device of FIG. 1 in accordance with an exemplary embodiment.

### DETAILED DESCRIPTION

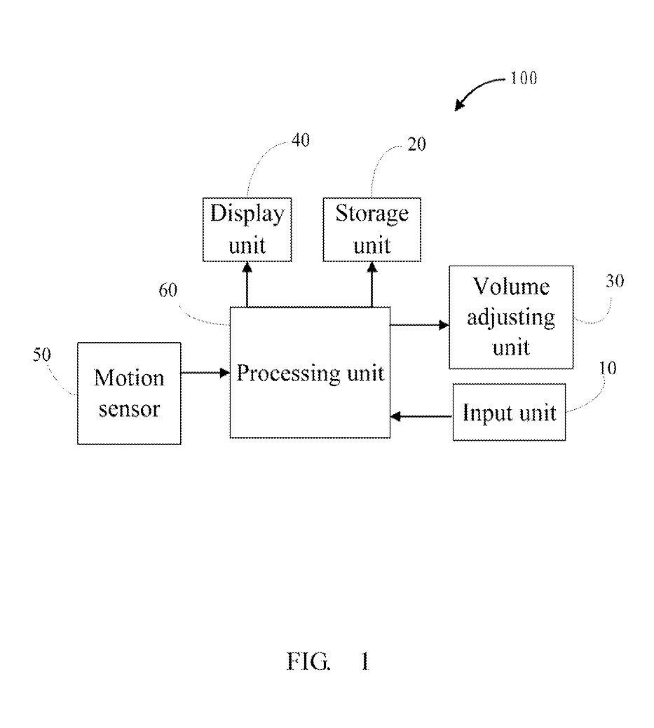

Referring to FIG. 1, an electronic device 100 in accordance with an exemplary embodiment is illustrated. The electronic device 100 includes an input unit 10, a storage unit 20, a volume adjusting unit 30, a display unit 40, a motion sensor 50, and a processing unit 60. The electronic device 100 may be a device such as a mobile phone, an E-book, or an audio player.

The storage unit 20 stores multimedia files.

The input unit 10 is configured to generate signals for controlling the operation of the electronic device 100 in response to user input.

The volume adjusting unit 30 is configured to adjust the volume of an opened audio file in response to user input.

The display unit 40 is configured to display information.

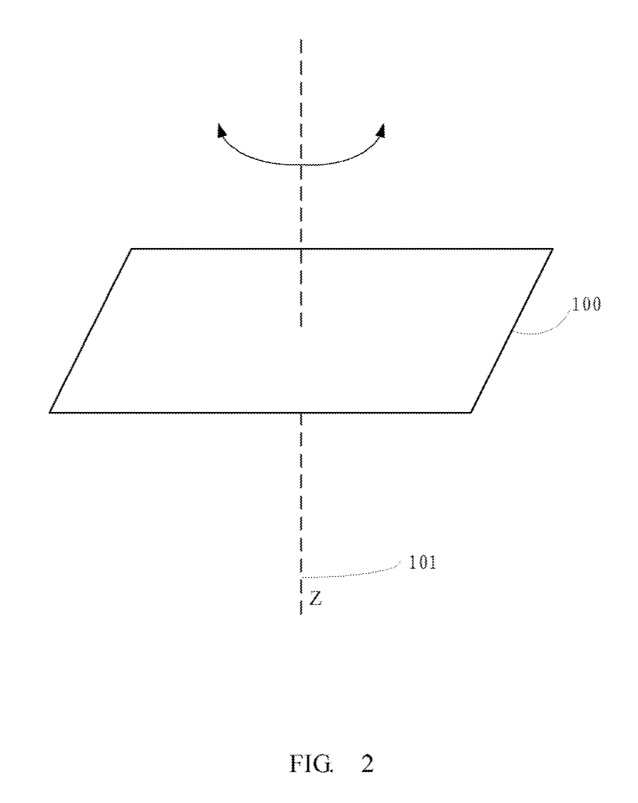

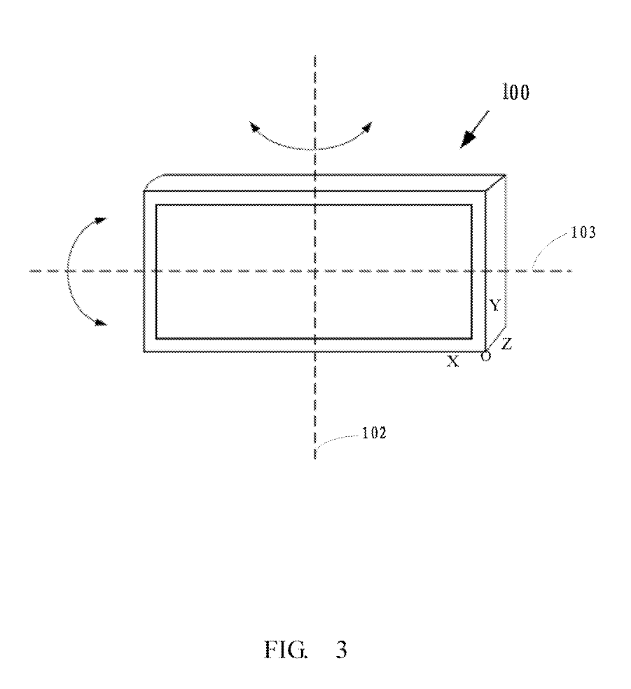

Referring to FIGS. 2 and 3, the motion sensor 50 senses the movement of the electronic device 100 according to a predetermined coordinate system. In this embodiment, the predetermined coordinate system is a 3D coordinate system, and the longitudinal direction of the electronic device 100 is the X axis, the wide direction is the Y axis, and the height direction is the Z axis. The electronic device 100 can rotate around three axes. A first axis 101 is perpendicular to XOY plane, a second axis 102 is parallel to the Y axis, and a third axis 103 is parallel to the X axis. In this embodiment, the motion sensor 50 may include an accelerometer and/or a gyroscope.

The processing unit 60 determines which of the three axes the electronic device 100 is rotated around and whether the rotation angle of the electronic device 100 reaches a predetermined angle based on the sensed movement, and executes a predetermined function if the angle reaches the predetermined angle.

In this embodiment, the processing unit 60 executes a first function if the rotation angle of the electronic device 100 is rotated around the first axis 101 to reach a first predetermined angle. For instance, the processing unit 60 rotates a currently displayed image a predetermined degree, such as 90 degrees, toward a predetermined direction, such as opposite to the rotation direction of the electronic device 100.

The processing unit 60 executes a second function if the rotation angle of the electronic device 100 is rotated around the second axis 102 clockwise or counterclockwise to reach a second predetermined angle. then executes a third function if the rotation angle of the electronic device 100 is rotated around the third axis 103 clockwise or counterclockwise to reach a third predetermined angle. In this embodiment, the third predetermined angle is larger than the second predetermined angle. The processing unit 60 flips a single page of a currently displayed file forward or backward if the rotation angle of the electronic device 100 is rotated around the second axis 102 to reach the second predetermined angle. The processing unit 60 flips multiple pages of the currently displayed file forward or backward if the rotation angle of the electronic device 100 is rotated around the second axis 102 to reach the third predetermined angle.

The processing unit 60 executes a fourth function if the rotation angle of the electronic device 100 is rotated around the third axis 103 clockwise or counterclockwise to reach a fourth predetermined angle. Then executes a fifth function if the rotation angle of the electronic device 100 is rotated around the third axis 103 clockwise or counterclockwise to reach a fifth predetermined angle. In this embodiment, the fifth predetermined angle is greater than the fourth predetermined angle. The processing unit 60 controls the volume adjusting unit 30 to decrease or increase a unit of the volume of a currently opened multimedia file if the rotation angle of the electronic device 100 is rotated around the third axis 103 clockwise or counterclockwise to reach the fourth predetermined angle. The processing unit 60 controls the volume adjusting unit 30 to continuously decrease or increase the volume of the currently opened multimedia file if the rotation angle of the electronic device 100 is rotated around the third axis 103 clockwise or counterclockwise to reach the fifth predetermined angle.

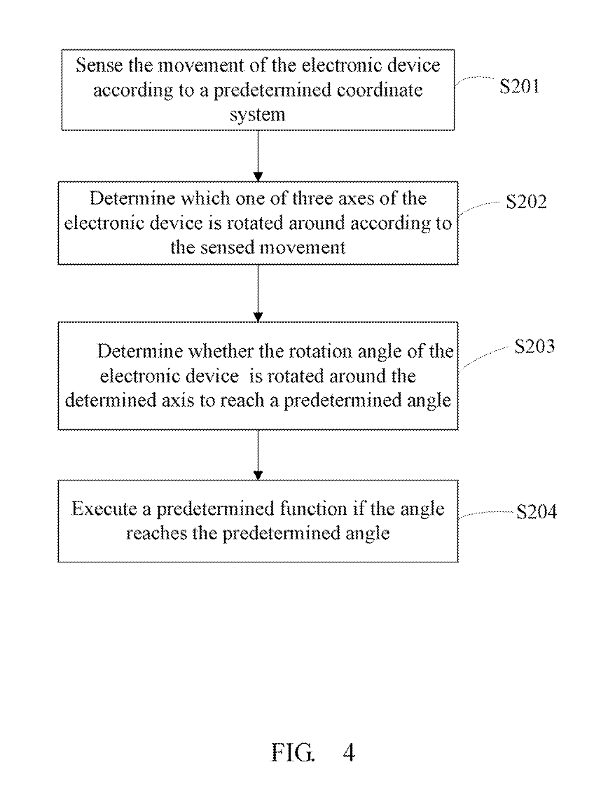

Referring to FIG. 4, a method for executing predetermined functions based on movement of the electronic device in accordance with an exemplary embodiment.

In step S201, the motion sensor 50 senses the movement of the electronic device 100 according to a predetermined coordinate system. In this embodiment, the predetermined coordinate system is a 3D coordinate system OXYZ, and the longitudinal direction of the electronic device 100 is the X axis, the wide direction is the Y axis, and the height direction is the Z axis. The electronic device 100 can be rotated around three axes. A first axis 101 is perpendicular to XOY plane, a second axis 102 is parallel to the Y axis, and a third axis 103 is parallel to the X axis.

In step S202, the processing unit 60 determines which one of three axes of the electronic device 100 is rotated around according to the sensed movement.

In step S203, the processing unit 60 determines whether the rotation angle of the electronic device 100 is rotated around the determined axis to reach a predetermined angle based on the sensed movement.

In step S204, the processing unit 60 executes a predetermined function if the angle reaches the predetermined angle.

If the processing unit 60 determines the rotation angle of the electronic device 100 is rotated around the first axis 101 to reach a first predetermined angle, the processing unit 60 rotates a currently displayed image a predetermined degree, such as 90 degrees, toward a predetermined direction, such as opposite to the rotation direction of the electronic device 100. If the rotation angle of the electronic device 100 is rotated around the second axis 102 to reach a second predetermined angle, the processing unit 60 flips a single page of a currently displayed file forward or backward. If the rotation angle of the electronic device 100 is rotated around the second axis 102 to reach, a third predetermined angle, the processing unit 60 flips multiple pages of the currently displayed file forward or backward. If the rotation angle of the electronic device 100 is rotated around the third axis 103 clockwise or counterclockwise to reach a fourth predetermined angle, the processing unit 60 controls the volume adjusting unit 30 to decrease or increase a unit of the volume of a currently opened multimedia file. If the rotation angle of the electronic device 100 is rotated around the third axis 103 clockwise or counterclockwise to reach a fifth predetermined angle, the processing unit 60 controls the volume adjusting unit 30 to continuously decrease or increase the volume of the currently opened multimedia file.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. An electronic device with motion sensing function, comprising:
a motion sensor configured to sense the movement of the electronic apparatus; and
a processing unit configured to determine which one of predetermined axes the electronic device rotated around and whether the rotation angle of the electronic device rotated around the determined axis reaches a predetermined angle based on the sensed movement, and execute a predetermined function if the angle reaches a predetermined angle.

2. The electronic device as described in claim 1, wherein the motion sensor is configured to sense the movement of the electronic device according to a predetermined 3D coordinate system, the longitudinal direction of the electronic device is the X axis of the 3D coordinate system, the wide direction is the Y axis of the 3D coordinate system, and the height direction is the Z axis of the 3D coordinate system; the predetermined axes comprises a first axis, a second axis, and a third axis, the first axis is perpendicular to XOY plane, the second axis is parallel to the Y axis, and the third axis is parallel to the X axis.

3. The electronic device as described in claim 1, wherein the processing unit is configured to execute a first function if the rotation angle of the electronic device is rotated around a first axis to reach a first predetermined angle.

4. The electronic device as described in claim 3, wherein the first function is to rotate a currently displayed image a predetermined degree toward a predetermined direction.

5. The electronic device as described in claim 1, wherein the processing unit is configured to execute a second function if the rotation angle of the electronic device is rotated around a second axis clockwise or counterclockwise to reach a second predetermined angle, and execute a third function if the angle the electronic device is rotated around the second axis to reach a third predetermined angle, the third predetermined angle is larger than the second predetermined angle.

6. The electronic device as described in claim 5, wherein the second function is to flip a single page of a currently displayed file forward or backward, and the third function is to flip multiple pages of the currently displayed file forward or backward.

7. The electronic device as described in claim 1, wherein the processing unit is configured to execute a fourth function if the rotation angle of the electronic device is rotated around a third axis to reach a fourth predetermined angle, and execute a fifth function if the rotation angle of the electronic device is rotated around the third axis clockwise or counterclockwise to reach a fifth predetermined angle.

8. The electronic device as described in claim 7, wherein the fourth function is to decrease or increase a unit of the volume of a currently opened multimedia file, and the fifth function is to continuously decrease or increase the volume of the currently opened multimedia file.

9. A method for executing predetermined functions based on movement of an electronic device comprising:
providing a motion sensor to sense the movement of the electronic apparatus;
determining which one of predetermined axes the electronic device rotated around according to the sensed movement;
determining whether the rotation angle of the electronic device is rotated around the determined axis to reach a predetermined angle; and
executing a predetermined function if the rotation angle of the electronic device is rotated around the determined axis to reach the predetermined angle.

10. The method as described in claim 9, wherein the motion sensor is configured to sense the movement of the electronic device according to a predetermined 3D coordinate system, the longitudinal direction of the electronic device is the X axis of the 3D coordinate system, the wide direction is the Y axis of the 3D coordinate system, and the height direction is the Z axis of the 3D coordinate system; the predetermined axes comprises a first axis, a second axis, and a third axis, the first axis is perpendicular to XOY plane, the second axis is parallel to the Y axis, and the third axis is parallel to the X axis.

11. The method as described in claim 9, wherein executing the predetermined function comprises:
executing a first function if the rotation angle of the electronic device is rotated around a first axis to reach a first predetermined angle.

12. The method as described in claim 11, wherein the first function is to rotate a currently displayed image a predetermined degree toward a predetermined direction.

13. The method as described in claim 9, wherein executing the predetermined function comprises:
executing a second function if the rotation angle of the electronic device is rotated around a second axis clockwise or counterclockwise to reach a second predetermined angle, and
executing a third function if the rotation angle of the electronic device is rotated around the second axis to reach a third predetermined angle, wherein the third predetermined angle is larger than the second predetermined angle.

14. The method as described in claim 13, wherein the second function is to flip a single page of a currently displayed file forward or backward, and the third function is to flip multiple pages of the currently displayed file forward or backward.

15. The method as described in claim 9, further comprising:
executing a fourth function if the rotation angle of the electronic device is rotated around a third axis to reach a fourth predetermined angle, and
executing a fifth function if the rotation angle of the electronic device is rotated around the third axis clockwise or counterclockwise to reach a fifth predetermined angle, wherein the fifth predetermined angle is larger than the fourth predetermined angle.

16. The method as described in claim 15, wherein the fourth function is to decrease or increase a unit of the volume of a currently opened multimedia file, and the fifth function is to continuously decrease or increase the volume of the currently opened multimedia file.

17. An electronic device with motion sensing function, comprising:
a display unit configured to display information;
a volume controlling unit configured to adjust the volume of an opened audio file in response to user input;
a motion sensor configured to sense the movements of the electronic device rotated around a plurality of predetermined axes; and
a processing unit configured to rotate a currently displayed image a predetermined degree toward a predetermined direction, control the display unit to flip pages, and control the volume adjusting unit to adjust the volume of the opened audio file if the rotation angles of the electronic device is rotated around the predetermined axes to reach predetermined angles correspondingly.

18. The electronic device as described in claim 17, wherein the motion sensor is configured to sense the movements of the electronic device according to a predetermined 3D coordinate system, the longitudinal direction of the electronic device is the X axis of the 3D coordinate system, the wide direction is the Y axis of the 3D coordinate system, and the height direction is the Z axis of the 3D coordinate system; the predetermined axes comprises a first axis, a second axis, and a third axis, the first axis is perpendicular to XOY plane, the second axis is parallel to the Y axis, and the third axis is parallel to the X axis.

19. The electronic device as described in claim 17, wherein the processing unit is configured to flip a single page of a currently displayed file forward or backward if the rotation angle of the electronic device is rotated around the second axis to reach a second predetermined angle, and flip multiple pages of the currently displayed file forward or backward if the angle the electronic device is rotated around the second axis to reach a third predetermined angle, the third predetermined angle is larger than the second predetermined angle.

20. The electronic device as described in claim 17, wherein the processing unit is configured to decrease or increase a unit of the volume of a currently opened multimedia file if the rotation angle of the electronic device is rotated around the third axis to reach a fourth predetermined angle, and continuously decrease or increase the volume of the currently opened multimedia file if the rotation angle of the electronic device is rotated around the third axis to reach a fifth predetermined angle, the fifth predetermined angle is larger than the fourth predetermined angle.
